(19) United States
(12) Patent Application Publication
(10) Pub. No.: US 2025/0275464 A1
(43) Pub. Date: Aug. 28, 2025

(54) PB-FREE DOUBLE PEROVSKITE SHORT-WAVE INFRARED MATERIALS AND PROCESSES FOR MAKING

(71) Applicants: Honda Motor Co., Ltd., Tokyo (JP); Utah State University, Logan, UT (US)

(72) Inventors: Gugang CHEN, Palo Alto, CA (US); Yi RAO, Logan, UT (US)

(21) Appl. No.: 18/589,345

(22) Filed: Feb. 27, 2024

(51) Int. Cl. H10K 85/50; C07F 19/00

(52) U.S. Cl. CPC H10K 85/50; C07F 19/005

(57) ABSTRACT

Aspects of the present disclosure generally relate to short-wave infrared materials and to processes for making short-wave infrared materials. In an aspect, a composition is provided that includes: a nitrogen-containing compound or ion thereof; and a Pb-free double perovskite material. The composition can be utilized as a short-wave infrared material. The perovskite materials described herein and compositions thereof show improved stability and can be fabricated at lower costs.

### FIELD

Aspects of the present disclosure generally relate to short-wave infrared materials and to processes for making short-wave infrared materials.

### BACKGROUND

Sunlight is made up of broadband energies from ultraviolet light and visible light to short-wave infrared (SWIR) light. The SWIR wavelength of light is defined as a range between 900 nanometers and 2,800 nanometers, which is not visible to the human eye. As a result, SWIR materials have become a significant focus of imaging, sensing, security, and electronic applications. The wavelength of light for SWIR allows for SWIR sensors to have a number of advantages over visible light sensors when utilized in a variety of applications including produce inspection, electronic board inspection, identifying and sorting, surveillance, anti-counterfeiting, process quality control, among others. For example, water vapor, fog, and certain materials such as silicon can be transparent when imaging with SWIR light. Unlike mid-wave infrared (MWIR) and long-wave infrared (LWIR) light, which are emitted from an object, SWIR light can be similar to visible light in that photons are reflected or absorbed by an object, thereby providing high resolution and strong contrast needed for high-resolution imaging.

Conventional SWIR sensors are based primarily on indium gallium arsenide (InGaAs), mercury cadmium telluride (HgCdTe), indium antimonide (InSb), lead sulfide (PbS), lead selenide (PbSe), and more recently lead (Pb)-based perovskites. Some of these materials are expensive, toxic, small in size, or unstable. In addition, conventional SWIR materials require complex fabrication processes.

There is a need for new and improved SWIR materials. There is also a need for new and improved process for making SWIR materials,

### SUMMARY

Aspects of the present disclosure generally relate to short-wave infrared materials and to processes for making short-wave infrared materials. Unlike conventional SWIR materials, SWIR materials described herein are Pb-free. SWIR materials of the present disclosure has unique light absorbance wavelengths from the visible to SWIR bands. The SWIR materials described herein can be incorporated into devices for detecting, sensing, localizing, and/or imaging various objects by SWIR light or radiation. Aspects described herein can find applications in automobiles, remote sensing, vehicle control, automated inspection, identifying and sorting, surveillance, anti-counterfeiting, and environmental chemical analysis, among other applications.

In an aspect is provided a composition that includes: a nitrogen-containing compound or ion thereof; and a Pb-free double perovskite material represented by Formula (I): A₂BCD₆ (I), wherein: A of Formula (I) is a first monovalent metal or ion thereof; B of Formula (I) is a second monovalent metal or ion thereof that is different from the first monovalent metal or ion thereof; C of Formula (I) is a trivalent metal or ion thereof; and each D of Formula (I) is a halogen or ion thereof, each D of Formula (I) being the same or different.

In another aspect is provided a short-wave infrared material comprising a composition described herein.

In another aspect is provided a process that includes: forming a precursor solution comprising: a first compound (AD) comprising a first monovalent metal cation (A) and a first monovalent anion (D); a second compound (BD) comprising a second monovalent metal cation (B) and a second monovalent anion (D), the second monovalent metal cation being different from the first monovalent metal cation; a third compound (CD₃) comprising a trivalent metal cation (C) and three third monovalent anions (D), each D being the same or different, and each D being the same or different; a nitrogen-containing compound; and a solvent; dispersing the precursor solution on a substrate; annealing the dispersed precursor solution on the substrate by heating the substrate at an annealing temperature that is from about 100° C. to about 300° C. to form a film composition comprising: a nitrogen-containing group or ion thereof; and a Pb-free double perovskite material represented by Formula (I): A₂BCD₆ (I).

In another aspect is provided a short-wave infrared material comprising a composition, the composition comprising: Cs₂AgBiBr₆, Cs₂AgSbBr₆, Cs₂AgInCl₆, Cs₂CuBiBr₆, Cs₂NaBiCl₆, or combinations thereof; and a nitrogen-containing compound or ion thereof, the nitrogen-containing compound or ion thereof comprising hydrazine, ammonia, methylamine, dimethylamine, trimethylamine, ethylamine, diethylamine, triethylamine, triisopropylamine, aziridine, diaziridine, formamidine, amidine, guanidine, hydrazinium ion, ammonium ion, methylammonium ion, dimethylammonium ion, trimethylammonium ion, ethylammonium ion, diethylammonium ion, triethylammonium ion, triisopropylammonium ion, aziridinium ion, diaziridinium ion, formamidinium ion, amidinium ion, guanidinium ion, or combinations thereof.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of its scope, for the disclosure may admit to other equally effective aspects.

FIG. 1 is an overlay of ultraviolet-visible-near infrared (UV-Vis-NIR) spectra showing absorption of SWIR materials prepared under different substrate temperatures (during spin coating) according to at least one aspect of the present disclosure.

FIG. 2 is an overlay of UV-Vis-NIR spectra showing absorption of SWIR materials prepared utilizing different molar amounts of hydrazinium iodide (NH₂NH₃I) to cesium bromide (CsBr) according to at least one aspect of the present disclosure.

### DETAILED DESCRIPTION

Aspects of the present disclosure generally relate to short-wave infrared materials and to processes for making short-wave infrared materials. As described above, traditional SWIR materials are composed of toxic materials such as InGaAs, HgCdTe, InSb, PbS, PbSe, and Pb-based perovskites. Some of these materials, however, are expensive, toxic, small in size, or unstable. In addition, conventional SWIR materials require complex fabrication processes. In contrast, aspects described herein provide stable, Pb-free double perovskite SWIR materials made in a simplified manner. In some aspects, the SWIR material includes a Pb-free double perovskite material and a nitrogen-containing compound (or ion thereof).

The SWIR materials described herein are substantially different than those previously reported. In some examples, Cs₂AgBiBr₆ was utilized as the double-perovskite material and NH₂NH₃⁺ cation was used as a nitrogen-containing compound. Here, and in some non-limiting aspects, an idea of the Pb-free perovskite is to use cationic ions for stable structures to create intermediate bands for SWIR absorption. The precursors for the SWIR materials described herein are universal, cheap, and toxicity-free, unlike existing alloy SWIR materials. The preparation procedure for the SWIR materials is relatively simple. The SWIR materials can have a broad absorbance that is from about 500 nm to about 2800 nm.

As used herein, a “composition” can include component(s) of the composition, reaction product(s) of two or more components of the composition, and/or a remainder balance of remaining starting component(s), or combinations thereof. Compositions of the present disclosure can be prepared by any suitable mixing process.

The use of headings is for purposes of convenience only and does not limit the scope of the present disclosure.

Aspects of the present disclosure generally relate to processes for forming compositions that include a Pb-free double perovskite material and a nitrogen-containing compound (or ion thereof). Such compositions can be utilized as an SWIR material. The compositions can be in the form of a film such as a thin film. In some aspects, the process includes forming a precursor solution that includes metal compounds, adding a doping agent (e.g., a nitrogen-containing compound) to the precursor solution, dispersing the resultant precursor solution on a substrate, and annealing the dispersed precursor solution on the substrate.

The Pb-free double perovskite material of the composition can be represented by Formula (I):

A₂BCD₆ (I),

wherein:
A of Formula (I) is a first monovalent metal or cation thereof;
B of Formula (I) is a second monovalent metal or cation thereof that is different from the first monovalent metal cation;
C of Formula (I) is a trivalent metal or cation thereof; and
each D of Formula (I) is, independently, a monovalent element or anion thereof, each D of Formula (I) being the same or different.

The process can include forming a precursor solution that includes a mixture comprising (a) a first compound that includes a first monovalent metal, a second compound that includes a second monovalent metal, a third compound that includes a trivalent metal, and a solvent. The first compound, the second compound, the third compound, or combinations thereof can include metal salts. According to some aspects, the metal precursor solution can be prepared by dissolving the first compound, the second compound, the third compound in a molar ratio of 2:1:1, respectively, in a suitable solvent.

The first compound may be represented by the general formula AD (or A⁺D⁻), wherein A (or A⁺) is the first monovalent metal and D (or D⁻) is a first monovalent anion. The first monovalent metal A (or A⁺) can include cesium (Cs), potassium (K), sodium (Na), lithium (Li), and/or a cation thereof. The first monovalent anion D (or D⁻) can include a halogen (or ion thereof) such as fluorine (F), chlorine (Cl), bromine (Br), or iodine (I), such as Cl, Br, or I, such as Cl or Br. Examples of first compounds can include, but are not limited to, CsCl, CsBr, CsI, KCl, KBr, KI, NaCl, NaBr, NaI, LiCl, LiBr, LiI, or combinations thereof.

The second compound may be represented by the general formula BD (or B⁺D⁻), wherein B (or B⁺) is the second monovalent metal and D (or D⁻) is a second monovalent anion. The second monovalent metal B (or B⁺) can include silver (Ag), copper (Cu), gold (Au), sodium (Na), or cation thereof, such as Ag, Cu, Na, and/or a cation thereof. The second monovalent anion D (or D⁻) can include a halogen (or ion thereof) such as F, Cl, Br, or I, such as Cl, Br, or I, such as Cl or Br. Examples of second compounds can include, but are not limited to, AgCl, AgBr, AgI, CuCl, CuBr, CuI, AuCl, AuBr, AuI, NaCl, NaBr, NaI, or combinations thereof, such as AgBr, CuBr, NaBr, or combinations thereof.

The third compound may be represented by the general formula CD₃ (or C³⁺(D⁻)₃), wherein C (or C³⁺) is the trivalent metal and D (or D⁻) is a third monovalent anion. In the general formula CD₃ (or C³⁺(D⁻)₃), there are three third monovalent anions. The trivalent metal C (or C³⁺) can include bismuth (Bi), antimony (Sb), or indium (In), or cation thereof, such as Bi, Sb, and/or cation thereof. The three third monovalent anions D (or D⁻) can include a halogen (or ion thereof) such as F, Cl, Br, or I, such as Cl, Br, or I, such as Cl or Br. Examples of third compounds can include, but are not limited to, BiCl₃, BiBr₃, BiI₃, SbCl₃, SbBr₃, SbI₃, InCl₃, InBr₃, InI₃, or combinations thereof, such as BiBr₃, SbBr₃, InCl₃, or combinations thereof, such as BiBr₃, SbBr₃, or combinations thereof.

Each D of Formula (I) can be the same or different.

Any suitable solvent, or solvent mixture, can be utilized for the precursor solution. Non-limiting examples of suitable solvents can include organic solvents such as dimethyl sulfoxide (DMSO), dimethylformamide (DMF), or combinations thereof.

The process can include introduction of a doping agent such as a nitrogen-containing compound or ion thereof to the precursor solution. Any suitable nitrogen-containing compound or ion thereof can be utilized as a doping agent. Illustrative, but non-limiting, examples of nitrogen-containing compounds can include hydrazine, ammonia, methylamine, dimethylamine, trimethylamine, ethylamine, diethylamine, triethylamine, triisopropylamine, aziridine, diaziridine, formamidine, amidine, guanidine, or combinations thereof. Illustrative, but non-limiting, examples of ions of nitrogen-containing compounds can include hydrazinium, ammonium, methylammonium, dimethylammonium, trimethylammonium, ethylammonium, diethylammonium, triethylammonium, triisopropylammonium, aziridinium, diaziridinium, formamidinium, amidinium, guanidinium, or combinations thereof. Salts, such as halide salts, of such ions of nitrogen-containing compounds

In at least one aspect, the nitrogen-containing compound comprises a protonated nitrogen atom (such as a nitrogen atom with a formal charge of +1) such that the nitrogen-containing compound comprises a cationic group. The nitrogen-containing compound can optionally include additionally include any suitable counter anion such as a halogen, such as Cl, Br, or I, such as Br or I. The nitrogen-containing compound can be made by protonating a nitrogen-containing compound with an acid or other material, such as hydrochloric acid (HCl), hydroboric acid (HBr), hydroiodic acid (HI), or combinations thereof. A non-limiting example of a suitable nitrogen-containing compound can include hydrazinium iodide (NH₂NH₃I).

The precursor solution that includes the metal salts and the doping agent can then be dispersed onto a heated substrate. Any suitable substrate can be utilized such as glass, sapphire, or polymer. The substrate can be a flexible or inflexible material. For example, glass, sapphire, or a flexible polymer can be utilized as the substrate. The substrate can be heated by utilizing a chuck.

During the dispersing of the precursor solution onto the substrate, the substrate can be heated at a temperature that is from about 90° C. to about 220° C., such as from about 100° C. to about 210° C., such as from about 100° C. to about 200° C., such as from about 110° C. to about 190° C., such as from about 120° C. to about 180° C., such as from about 130° C. to about 170° C., such as from about 140° C. to about 160° C., or from about 130° C. to about 180° C., such as from about 140° C. to about 170° C., such as from about 150° C. to about 160° C., though other values are contemplated. Any of the foregoing numbers can be used singly to describe an open-ended range or in combination to describe a close-ended range.

The precursor solution can be dispersed onto the substrate by any suitable means to form a thin film of precursor solution on the substrate. A non-limiting example of dispersing is chemical solution deposition. In general, chemical solution deposition is a process for depositing thin films on a substrate surface by chemical reaction or electrochemical reaction to form a film. Chemical solution deposition can be utilized to accurately control the stoichiometric ratio and provide a film with good uniformity. A non-limiting example of chemical solution deposition that can be utilized includes spin coating. Spin coating includes spinning (or rotating) the substrate at a suitable speed and dispersing the precursor solution onto the rotating substrate. For example, the precursor solution can form a thin film on a rotating substrate. The substrate can be rotated at a suitable speed to disperse the precursor solution (and form a thin film of precursor solution) but not at such an excessive speed to dislodge the precursor solution from the substrate. Suitable rotation speeds can include 100 revolutions per minute or more, 3,000 rpm or less, or combinations thereof, such as from about 500 rpm to about 3,000 rpm, such as from about 1,000 rpm to about 2,000 rpm, such as about 1,500 rpm, though other values are contemplated. Any of the foregoing numbers can be used singly to describe an open-ended range or in combination to describe a close-ended range. The precursor solution can be dispersed onto the substrate for a period of about 1 second or more, 20 minutes or less, or combinations thereof, such as from about 10 seconds to about 15 minutes, such as from about 20 seconds to about 10 minutes, such as from about 30 seconds to about 5 minutes, or from about 5 seconds to about 1 minute, such as about 20 seconds, though other values are contemplated. Any of the foregoing numbers can be used singly to describe an open-ended range or in combination to describe a close-ended range.

A spin-coater chuck can be utilized to heat the substrate at those temperatures described above while dispersing the precursor solution onto the heated substrate. Optionally, spin coating can be performed in a glove box, under a non-reactive gas (such as N₂ or Ar), or combinations thereof.

In some aspects, and prior to dispersing the precursor solution onto the substrate, the precursor solution can be optionally pre-heated, the substrate can be optionally pre-heated, or combinations thereof. Pre-heating of the precursor solution and/or the substrate prior dispersing can affect the crystallization rate. For example, pre-heating both the precursor solution and substrate can cause the solvent in the solution can evaporate more quickly, which can increase the nucleation density and increase crystal perovskite strength, resulting in better film quality. This better film quality can have higher light absorption efficiency, and when the film is in a device, the current of the device can be increased reduced. Because the substrate temperature can be the same as (or similar to) the precursor solution temperature during spin-coating, the solution will not be cooled.

In some aspects, the substrate can be pre-heated prior to dispersion at a substrate pre-heating temperature that is from about 40° C. to about 120° C., such as from about 50° C. to about 110° C., such as from about 60° C. to about 100° C., such as from about 70° C. to about 90° C., such as from about 75° C. to about 85° C., or about 70° C., or about 80° C., or about 90° C., though other values are contemplated. Any of the foregoing numbers can be used singly to describe an open-ended range or in combination to describe a close-ended range.

In some aspects, the precursor solution comprising the first compound, second compound, third compound, nitrogen-containing compound, and solvent can be optionally pre-heated at a precursor solution pre-heating temperature that is from about 40° C. to about 120° C., such as from about 50° C. to about 110° C., such as from about 60° C. to about 100° C., such as from about 70° C. to about 90° C., such as from about 75° C. to about 85° C., or about 70° C., or about 80° C., or about 90° C., though other values are contemplated. Any of the foregoing numbers can be used singly to describe an open-ended range or in combination to describe a close-ended range.

Under the spin-coating process, and as described above, appropriate pre-heating temperatures can promote crystallization and the formation of a uniform film with good photoelectric performance.

The dispersed solution can then be annealed upon the substrate. A purpose of the annealing can include forming a pure-phase substance, eliminating excess material. The pure-phase substance can also promote continuous growth of grains and an increase in size, further improving the stability of the film. In some aspects, a thin film of metal precursor solution is annealed on the substrate. According to some aspects, depending on the annealing conditions, and for example, the chemical composition of the precursor solution, the wavelength of maximum SWIR absorbance of the resulting perovskite material can change. Annealing can optionally be performed under vacuum conditions. Annealing can be performed at an annealing temperature that is from about 40° C. to about 300° C., such as from about 100° C. to about 300° C., such as from about 125° C. to about 250° C., such as from about 150° C. to about 225° C., such as from about 170° C. to about 200° C., such as from about 180° C. to about 190° C., such as from about 185° C. to about 190° C., though other values are contemplated. Any of the foregoing numbers can be used singly to describe an open-ended range or in combination to describe a close-ended range. Annealing can be done for any suitable period. Non-limiting examples of annealing times are from about 1 minute to about 60 minutes, such as from about 5 minutes to about 45 minutes, such as from about 10 minutes to about 30 minutes, or from about 15 minutes to about 30 minutes, though other values are contemplated. Any of the foregoing numbers can be used singly to describe an open-ended range or in combination to describe a close-ended range. The annealing forms a composition that includes a Pb-free double perovskite material and a nitrogen-containing compound. This composition which can be in the form of a film can be utilized as an SWIR material.

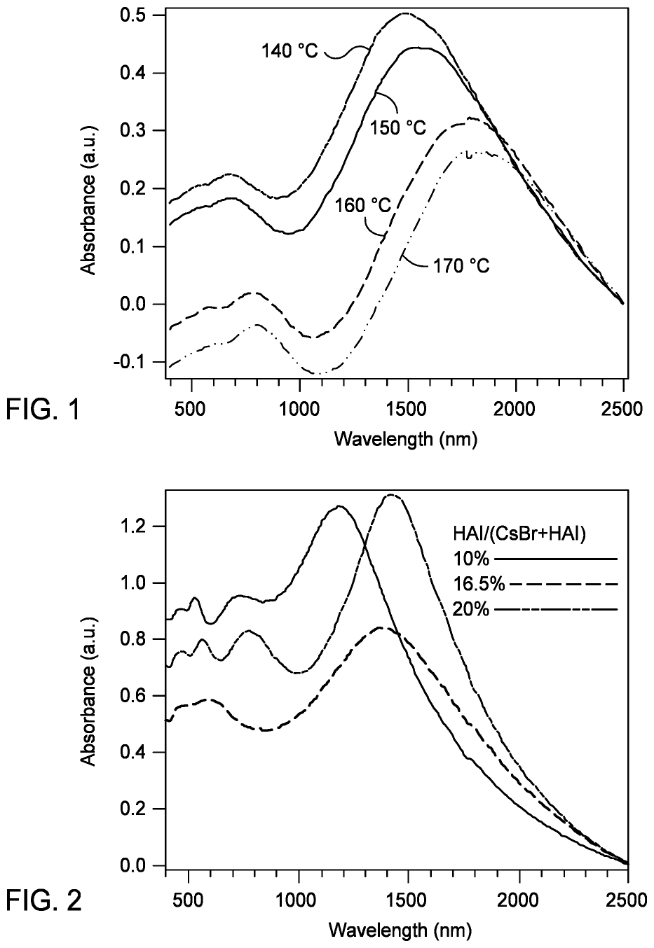

The inventors found that annealing conditions can be operative (or adapted) to determine a wavelength of maximum SWIR absorbance of the film. For example, higher annealing temperatures can provide a composition with a higher wavelength of maximum SWIR absorbance than a composition annealed at lower annealing temperatures (See FIG. 1). That is, aspects described herein can be utilized to tune wavelengths of maximum SWIR absorbance of the films and thereby use the SWIR materials in various applications.

The inventors also found that the molar amount of the nitrogen-containing compound divided by a total molar amount of the first compound plus the nitrogen-containing compound in the precursor solution (see Equation 1) can be operative to (or adapted to) determine a wavelength of maximum SWIR absorbance of the film:

$$\% value = \frac{nitrogen - containing compound}{nitrogen - containing compound + first compound} \times 100 \% \qquad ( Equation 1 )$$

wherein: nitrogen-containing compound in Equation 1 is the molar amount of nitrogen-containing compound in the precursor solution; and first compound in Equation 1 is the molar amount of the first compound in the precursor solution; and % value is a mol/mol % value.

For example, and in some aspects, a higher mol/mol % value for Equation 1 can provide a composition with a higher wavelength of maximum SWIR absorbance than a composition with lower % value (See FIG. 2). That is, aspects described herein can be utilized to tune wavelengths of maximum SWIR absorbance of the films and thereby use the SWIR materials in various applications. In some aspects, the mol/mol % value as determined by Equation 1 is from about 5 mol/mol % to about 30 mol/mol %, such as from about 10 mol/mol % to about 20 mol/mol %, such as from about 12 mol/mol % to about 18 mol/mol %, or about 10 mol/mol %, about 16.5 mol/mol %, or about 20 mol/mol %, though other values are contemplated. Any of the foregoing numbers can be used singly to describe an open-ended range or in combination to describe a close-ended range.

In various aspects, Equation 1 can be re-written as Equation 2:

$$\% value = \frac{{NH}_{2} {NH}_{3} I}{CsBr + {NH}_{2} {NH}_{3} I} \qquad ( Equation 2 )$$

wherein: NH₂NH₃I is the molar amount of hydrazinium iodide in the precursor solution; CsBr is the molar amount of cesium bromide in the precursor solution; and % value is a mol/mol % value. The mol/mol % value can be those values described above.

A non-limiting example procedure for forming a thin film comprising compositions described herein can be performed as follows: A precursor solution prepared by dissolving the first compound, the second compound, and the third compound in an organic solvent. The nitrogen-containing compound (e.g., NH₂NH₃I) is added to the precursor solution. The resultant precursor solution is pre-heated to a temperature of about 60° C. to about 100° C. A substrate is also pre-heated to a temperature of about 60° C. to about 100° C. The pre-heated substrate is placed on a spin-coater chuck. The precursor solution is then spin-coated on the substrate for a period of about 1 minute or less at a temperature of about 130° C. to about 180° C. while rotating the substrate at about 1,000 rpm to about 2,000 rpm. The spin coated substrate is then annealed at an annealing temperature that is from about 170° C. to about 205° C. for a period of about 10 minutes to about 1 hour. The resulting thin film comprising the double perovskite and the nitrogen-containing compound was then cooled in a vacuum chamber at suitable pressures.

Aspects of the present disclosure also generally relate to compositions that include: a Pb-free double perovskite material; and a nitrogen-containing compound or ion thereof. Such compositions can be utilized as an SWIR material. The compositions can be in the form of a film.

The Pb-free double perovskite material of compositions described herein can be represented by Formula (I) as described above. Non-limiting examples of the nitrogen-containing compound (or ion thereof) are also described above.

In some aspects, a molar ratio of the nitrogen-containing group or ion thereof to the Pb-free double perovskite material in the composition is from about 0.05:1 to about 4:1, such as from about 0.5:1 to about 3:1, such as from about 1:1 to about 2:1.

Pb-free double perovskite material of compositions described herein can be represented by Formula (II):

Cs₂BCD₆ (II),

Cs of Formula (II) is cesium. B of Formula (II) can be a monovalent metal such as Ag, Cu, Au, Na, and/or cation thereof, such as Ag, Cu, Na, and/or cation thereof. C of Formula (II) can be a trivalent metal such as Bi, Sb, In, and/or cation thereof, such as Bi, Sb, and/or cation thereof. Each D of Formula (II) can be, independently, a halogen such as F, Cl, Br, I, or combinations thereof, such as Cl, Br, I, or combinations thereof such as Cl, Br, or combinations thereof. Each D of Formula (II) being the same or different.

Illustrative, but non-limiting, examples of compositions that can be formed by processes described herein include Cs₂AgBiBr₆, Cs₂AgSbBr₆, Cs₂AgInCl₆, Cs₂CuBiBr₆, and Cs₂NaBiCl₆, among many others.

Compositions described herein can be in the form of films. The films can be utilized as an SWIR material. Films described herein can have any suitable thickness. In some aspects, a film described herein has a thickness that is from about 5 nm to about 2,000 nm (about 2 μm), such as from about 10 nm to about 1,750 nm (about 1.75 μm), such as from about 100 nm to about 1000 nm (about 1 μm), such as from about 125 nm to about 900 nm, such as from about 150 to about 800 nm, such as from about 200 nm to about 700 nm, such as from about 250 nm to about 600 nm, such as from about 300 nm to about 500 nm, or from about 150 nm to about 250 nm, such as about 200 nm, though other values are contemplated. Any of the foregoing numbers can be used singly to describe an open-ended range or in combination to describe a close-ended range.

Processes described herein can enable growth of a film described herein comprising crystals having any suitable average single crystal grain size. In some aspects, a film described herein has an average single crystal grain size that is from about 10 nm to about 1000 nm (about 1 μm), such as from about 50 nm to about 750 nm, such as from about 80 nm to about 600 nm, such as from about 100 nm to about 500 nm, such as from about 200 nm to about 400 nm, though other values are contemplated. Any of the foregoing numbers can be used singly to describe an open-ended range or in combination to describe a close-ended range. Average grain size is measured by optical microscope. The grain size is the lateral size of each crystal. Because the film is formed by merging single crystals, a single grain refers to a single crystal.

The following examples are put forth so as to provide those of ordinary skill in the art with a complete disclosure and description of how to make and use aspects of the present disclosure, and are not intended to limit the scope of aspects of the present disclosure. Efforts have been made to ensure accuracy with respect to numbers used (for example, amounts, dimensions, etc.) but some experimental errors and deviations should be accounted for.

### EXAMPLES

Examples of compositions described herein were made using various materials set out in the Materials and are described further below. Selected properties of the compositions were measured using Test Methods.

### Materials

Cesium bromide (CsBr, 99%), silver bromide (AgBr, 99.5%), and anhydrous dimethyl sulfoxide (DMSO) were purchased from Alfa Aesar. Bismuth (III) bromide (BiBr₃), hydrazine (NH₂NH₂), hydroiodic acid (HI, 55-58% wt/wt aq. sol.), isopropyl alcohol (99%), and Hellmanex III solution were purchased from Sigma-Aldrich. All chemicals were used as received without further purification.

Hydrazinium iodide (NH₂NH₃I, also referred to as HAI) was used a non-limiting example of a nitrogen-containing compound. NH₂NH₃I was prepared by mixing NH₂NH₂ and hydroiodic acid. Other nitrogen-containing compounds can be prepared similarly.

### Test Methods

The UV and short-wave IR absorbance spectra were collected using a spectrophotometer (Varian Cary 5000 UV-Vis-NIR spectrometer) in the range of 300 nm to 2500 nm.

### Example: Preparation of Compositions as Thin Films

Precursor solution. A precursor solution was prepared by dissolving BiBr₃ (about 0.5 mmol to about 0.6 mmol), AgBr (about 0.5 mmol to about 0.6 mmol), and CsBr (about 1 mmol to about 1.2 mmol) in 1 milliliter (ml) of anhydrous DMSO in a vial covered with aluminum foil, then stirred at about room temperature allowing the materials to be fully dissolved before use. The solution was then doped with NH₂NH₃I (HAI). The NH₂NH₃I was added to the solution by keeping the total amount of Cs⁺ and NH₂NH₃⁺ as twice as that of AgBr or BiBr₃.

Other precursor solutions were also prepared in order to form other Pb-free double perovskite material such as Cs₂AgSbBr₆, Cs₂AgInCl₆, Cs₂CuBiBr₆, and Cs₂NaBiCl₆. For example, Bi can be replaced with other trivalent metals such as Sb or In; Ag can be replaced by other monovalent metals such as Cu, Au, or Na; Br can be replaced with other monovalent anions such as Cl or I. Other nitrogen-containing compounds can be used instead of NH₂NH₃I. For example, halide salts of ammonia, methylamine, trimethylamine, ethylamine, diethylamine, aziridine, formamidine, amidine, or guanidine, among other salts of nitrogen-containing compounds can be utilized. Other solvents such as dimethylformamide can be utilized.

Cleaning of glass substrate. A glass substrate was first sonicated with Hellmanex III solution for about 30 minutes at a temperature of about 30° C. to about 35° C. The substrate was then cleaned with distilled water three to five times with sonicating for about 30 minutes. The substrate was then sonicated in isopropyl alcohol (99%) for three to five times for about 30 minutes. The substrate was illuminated in an ozone (O₃) cleaner for about 30 minutes. In addition, other substrates such as sapphire substrates can be utilized.

Thin film fabrication. For thin film formation, the fabrication included the following operations: (1) The precursor solution was prepared as described above and then pre-heated to a temperature of about 70° C. (2) The glass substrate was pre-heated to a temperature of about 70° C. (3) The pre-heated glass substrate was placed on a spin-coater chuck, and the substrate was spin-coated with the pre-heated precursor solution for a period of about 20 seconds at a temperature of about 140° C. to about 170° C. and while rotating the substrate at about 1,500 rpm. (4) The spin-coated substrate was then annealed at an annealing temperature that was from about 185° C. to about 190° C.) for a period of about 30 minutes. The NH₂NH₃I-doped Cs₂BiAgBr₆ perovskite thin film was then cooled down by moving the film to a vacuum chamber where the pressure reached from about 0.01 Pa to about 2.0 Pa.

FIG. 1 shows UV-vis-NIR absorbance spectra of example NH₂NH₃I-doped Cs₂AgBiBr₆ perovskite thin films prepared under different spin-coating temperatures of about 140° C., about 150° C., about 160° C., or about 170° C. Two prominent peaks appear for all the thin films, a lower energy peak that is from about 1400 nm to about 1900 nm and a higher energy peak that is from about 700 to about 800 nm. The SWIR peak becomes longer as the spin-coating temperature increases. Overall, the data in FIG. 1 indicates that different spin-coating temperatures can shift the absorption peaks and that aspects described herein can be utilized to tune wavelengths of maximum SWIR absorbance of the films and thereby use the SWIR materials in various applications.

FIG. 2 shows UV-vis-NIR absorbance spectra of example NH₂NH₃I-doped Cs₂AgBiBr₆ perovskite thin films prepared using varying ratios of NH₂NH₃I (HAI) and keeping the total molar amount of Cs⁺ and NH₂NH₃⁺ as twice as that of AgBr or BiBr₃. For the non-limiting data shown in FIG. 2, the spin-coating temperature was about 150° C. while the substrate was rotated at about 1,500 rpm. Various amounts of NH₂NH₃I (e.g., about 10 mol/mol %, about 16.5 mol/mol %, and about 20 mol/mol %) in the precursor solution were investigated and calculated by Equation 2:

$$\% value = \frac{{NH}_{2} {NH}_{3} I}{CsBr + {NH}_{2} {NH}_{3} I} \qquad ( Equation 2 )$$

The data in FIG. 2 shows that the SWIR peak shifts when changing the molar amount of nitrogen-containing compound (in this example, NH₂NH₃I). Overall, the data in FIG. 2 indicates that different amounts of the nitrogen-containing compound can shift the absorption peaks and that aspects described herein can be utilized to tune wavelengths of maximum SWIR absorbance of the films and thereby use the SWIR materials in various applications. The examples also illustrate that aspects described herein can be utilized for forming chemically-doped Pb-free SWIR materials.

Aspects of the present disclosure generally relate to short-wave infrared materials and to processes for making short-wave infrared materials. Unlike conventional SWIR materials, SWIR materials of the present disclosure can have a large area and high quantum efficiency. In further contrast to conventional SWIR materials, SWIR materials described herein are toxicity-free, easy to fabricate, and can be formed with much lower costs. The Pb-free double metallic perovskites can be utilized in myriad applications such as in automobiles, remote sensing, vehicle control, automated inspection, identifying and sorting, surveillance, anti-counterfeiting, and environmental chemical analysis, among other applications.

Aspects described herein generally relate to short-wave infrared materials and to processes for making short-wave infrared materials. Relative to conventional technologies, aspects described herein provide stable, Pb-free double perovskite SWIR materials that can be made in a simplified manner. In some aspects, the SWIR material includes a Pb-free double perovskite material and a nitrogen-containing compound (or ion thereof).

### Aspects Listing

The present disclosure provides, among others, the following aspects, each of which can be considered as optionally including any alternate aspects:
Clause A1. A composition, comprising:
a nitrogen-containing compound or ion thereof; and
a Pb-free double perovskite material represented by Formula (I):

A₂BCD₆ (I),

wherein:
A of Formula (I) is a first monovalent metal or ion thereof;
B of Formula (I) is a second monovalent metal or ion thereof that is different from the first monovalent metal or ion thereof;
C of Formula (I) is a trivalent metal or ion thereof; and
each D of Formula (I) is a halogen or ion thereof, each D of Formula (I) being the same or different.
Clause A2. The composition of Clause A1, wherein a molar ratio of the nitrogen-containing compound or ion thereof to the Pb-free double perovskite material in the composition is from about 0.05:1 to about 4:1.
Clause A3. The composition of Clause A1 or Clause A2, wherein the nitrogen-containing compound comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, an ion thereof, or combinations thereof.
Clause A4. The composition of any one of Clauses A1-A3, wherein each D of Formula (I) is, independently, Cl, Br, I, ion thereof, or combinations thereof.
Clause A5. The composition of any one of Clauses A1-A4, wherein A of Formula (I) is Cs, K, Na, Li, or ion thereof.
Clause A6. The composition of any one of Clauses A1-A5, wherein:
B of Formula (I) comprises Ag, Cu, Au, Na, or ion thereof;
C of Formula (I) comprises Bi, Sb, In, or ion thereof; or
combinations thereof.
Clause A7. The composition of any one of Clauses A1-A6, wherein the Pb-free double perovskite material is represented by Formula (II):

Cs₂BCD₆ (II),

wherein:
Cs of Formula (II) is cesium or ion thereof;
B of Formula (II) is Ag, Cu, Na, or ion thereof;
C of Formula (II) is Bi, Sb, or ion thereof; and
each D of Formula (II) is, independently, Cl, Br, or ion thereof, each D of Formula (I) being the same or different.
Clause A8. The composition of any one of Clauses A1-A7, wherein the Pb-free double perovskite material is selected from the group consisting of Cs₂AgBiBr₆, Cs₂AgSbBr₆, Cs₂AgInCl₆, Cs₂CuBiBr₆, and Cs₂NaBiCl₆.
Clause A9. A short-wave infrared material comprising the composition of any one of Clauses A1-A8.
Clause B1. A process, comprising:
forming a precursor solution comprising:
   a first compound (AD) comprising a first monovalent metal cation (A) and a first monovalent anion (D);
   a second compound (BD) comprising a second monovalent metal cation (B) and a second monovalent anion (D), the second monovalent metal cation being different from the first monovalent metal cation;
   a third compound (CD₃) comprising a trivalent metal cation (C) and three third monovalent anions (D), each D being the same or different, and each D being the same or different;
   a nitrogen-containing compound; and
   a solvent;
dispersing the precursor solution on a substrate;
annealing the dispersed precursor solution on the substrate by heating the substrate at an annealing temperature that is from about 100° C. to about 300° C. to form a film composition comprising:
   a nitrogen-containing group or ion thereof; and
   a Pb-free double perovskite material represented by Formula (I):

A₂BCD₆ (I).
Clause B2. The process of Clause B1, further comprising: pre-heating the precursor solution at a pre-heating temperature that is from about 40° C. to about 150° C. prior to the dispersing the precursor solution on the substrate.
Clause B3. The process of Clause B1 or Clause B2, wherein the dispersing the precursor solution on the substrate is performed by spin coating the precursor solution on the substrate.
Clause B4. The process of Clause B3, wherein the spin coating the precursor solution comprises:
rotating the substrate at 100 rpm to about 3,000 rpm; and
heating the substrate at a spin-coating temperature that is from about 90° C. to about 220° C.
Clause B5. The process of any one of Clauses B1-B4, wherein the temperature at which the precursor solution is dispersed on the substrate is operative to determine a wavelength of maximum SWIR absorbance of the film composition.
Clause B6. The process of any one of Clauses B1-B5, wherein a mol/mol % value in the precursor solution determined by Equation 1 is operative to determine a wavelength of maximum SWIR absorbance of the film composition:

$$\frac{nitrogen - containing compound}{nitrogen - containing compound + first compound} \times 100 \% \qquad ( Equation 1 )$$

wherein:
the nitrogen-containing compound in Equation 1 is a molar amount of the nitrogen-containing compound in the precursor solution; and
first compound in Equation 1 is a molar amount of the first compound in the precursor solution.
Clause B7. The process of Clause B6, wherein the mol/mol % value as determined by Equation 1 is from about 5 mol/mol % to about 30 mol/mol %.
Clause B8. The process of any one of Clauses B1-B7, wherein each of the monovalent anions (D) is, independently, Cl⁻, Br⁻, I⁻, or combinations thereof.
Clause B9. The process of any one of Clauses B1-B8, wherein:
the first compound comprises cesium monovalent cation (Cs⁺), potassium monovalent cation (K⁺), sodium monovalent cation (Na⁺), or lithium monovalent cation (Li⁺);
the second compound comprises silver monovalent cation (Ag⁺), copper monovalent cation (Cu⁺), gold monovalent cation (Au⁺), or sodium monovalent cation (Na⁺);
the third compound comprises bismuth trivalent cation (Bi³⁺), antimony trivalent cation (Sb³⁺), or indium trivalent cation (In³⁺);
or combinations thereof.
Clause C1. A short-wave infrared material comprising a composition, the composition comprising:
Cs₂AgBiBr₆, Cs₂AgSbBr₆, Cs₂AgInCl₆, Cs₂CuBiBr₆, Cs₂NaBiCl₆, or combinations thereof; and
a nitrogen-containing compound or ion thereof, the nitrogen-containing compound or ion thereof comprising hydrazine, ammonia, methylamine, dimethylamine, trimethylamine, ethylamine, diethylamine, triethylamine, triisopropylamine, aziridine, diaziridine, formamidine, amidine, guanidine, hydrazinium ion, ammonium ion, methylammonium ion, dimethylammonium ion, trimethylammonium ion, ethylammonium ion, diethylammonium ion, triethylammonium ion, triisopropylammonium ion, aziridinium ion, diaziridinium ion, formamidinium ion, amidinium ion, guanidinium ion, or combinations thereof.
Clause C2. The short-wave infrared material of Clause C1, wherein: the nitrogen-containing compound or ion thereof of the composition comprises hydrazine, hydrazinium, or combinations thereof.

Where isomers of a named molecule group exist (for example, n-butyl, iso-butyl, sec-butyl, and tert-butyl), reference to one member of the group (for example, n-butyl) shall expressly disclose the remaining isomers (for example, iso-butyl, sec-butyl, and tert-butyl) in the family unless specified to the contrary or the context clearly indicates otherwise. Likewise, reference to a named molecule without specifying a particular isomer (for example, butyl) expressly discloses all isomers (for example, n-butyl, iso-butyl, sec-butyl, and tert-butyl) unless specified to the contrary or the context clearly indicates otherwise. When a compound is described herein such that a particular isomer, enantiomer or diastereomer of the compound is not specified, for example, in a formula or in a chemical name, that description is intended to include each isomer and enantiomer of the compound described individual or in any combination unless specified to the contrary or the context clearly indicates otherwise.

As is apparent from the foregoing general description and the specific aspects, while forms of the aspects have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, an element, a group of elements, or a method is preceded with the transitional phrase “comprising,” it is understood that we also contemplate the same composition, method. or group of elements with transitional phrases “consisting essentially of,” “consisting of,” “selected from the group of consisting of,” or “Is” preceding the recitation of the composition, element, elements, or method, and vice versa, such as the terms “comprising,” “consisting essentially of,” “consisting of” also include the product of the combinations of elements listed after the term.

For purposes of this present disclosure, and unless otherwise specified, all numerical values within the detailed description and the claims herein are modified by “about” or “approximately” the indicated value, and consider experimental error and variations that would be expected by a person having ordinary skill in the art. For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. For example, the recitation of the numerical range 1 to 5 includes the subranges 1 to 4, 1.5 to 4.5, 1 to 2, among other subranges. As another example, the recitation of the numerical ranges 1 to 5, such as 2 to 4, includes the subranges 1 to 4 and 2 to 5, among other subranges. Additionally, within a range includes every point or individual value between its end points even though not explicitly recited. For example, the recitation of the numerical range 1 to 5 includes the numbers 1, 1.5, 2, 2.75, 3, 3.80, 4, 5, among other numbers. Thus, every point or individual value may serve as its own lower or upper limit combined with any other point or individual value or any other lower or upper limit, to recite a range not explicitly recited.

As used herein, the indefinite article “a” or “an” shall mean “at least one” unless specified to the contrary or the context clearly indicates otherwise. For example, aspects comprising “a metal” include aspects comprising one, two, or more metals, unless specified to the contrary or the context clearly indicates only one metal is included.

While the foregoing is directed to aspects of the present disclosure, other and further aspects of the disclosure may be devised without departing from the basic scope thereof, and the scope thereof is determined by the claims that follow.

1. A composition, comprising:
a nitrogen-containing compound or ion thereof; and
a Pb-free double perovskite material represented by Formula (I):
A₂BCD₆ (I),
wherein:
A of Formula (I) is a first monovalent metal or ion thereof;
B of Formula (I) is a second monovalent metal or ion thereof that is different from the first monovalent metal or ion thereof;
C of Formula (I) is a trivalent metal or ion thereof; and
each D of Formula (I) is a halogen or ion thereof, each D of Formula (I) being the same or different.

2. The composition of claim 1, wherein a molar ratio of the nitrogen-containing compound or ion thereof to the Pb-free double perovskite material in the composition is from about 0.05:1 to about 4:1.

3. The composition of claim 1, wherein the nitrogen-containing compound comprises hydrazine, ammonia, methylamine, dimethylamine, trimethylamine, ethylamine, diethylamine, triethylamine, triisopropylamine, aziridine, diaziridine, formamidine, amidine, guanidine, an ion thereof, an ion thereof, or combinations thereof.

4. The composition of claim 1, wherein each D of Formula (I) is, independently, Cl, Br, I, ion thereof, or combinations thereof.

5. The composition of claim 1, wherein A of Formula (I) is Cs, K, Na, Li, or ion thereof.

6. The composition of claim 1, wherein:
B of Formula (I) comprises Ag, Cu, Au, Na, or ion thereof;
C of Formula (I) comprises Bi, Sb, In, or ion thereof; or
combinations thereof.

7. The composition of claim 1, wherein the Pb-free double perovskite material is represented by Formula (II):
Cs₂BCD₆ (II),
wherein:
Cs of Formula (II) is cesium or ion thereof;
B of Formula (II) is Ag, Cu, Na, or ion thereof;
C of Formula (II) is Bi, Sb, or ion thereof; and
each D of Formula (II) is, independently, CI, Br, or ion thereof, each D of Formula (I) being the same or different.

8. The composition of claim 7, wherein the Pb-free double perovskite material is selected from the group consisting of Cs₂AgBiBr₆, Cs₂AgSbBr₆, Cs₂AgInCl₆, Cs₂CuBiBr₆, and Cs₂NaBiCl₆.

9. A short-wave infrared material comprising the composition of claim 1.

10. A process, comprising:
forming a precursor solution comprising:
a first compound (AD) comprising a first monovalent metal cation (A) and a first monovalent anion (D);
a second compound (BD) comprising a second monovalent metal cation (B) and a second monovalent anion (D), the second monovalent metal cation being different from the first monovalent metal cation;
a third compound (CD₃) comprising a trivalent metal cation (C) and three third monovalent anions (D), each D being the same or different, and each D being the same or different;
a nitrogen-containing compound; and
a solvent;
dispersing the precursor solution on a substrate;
annealing the dispersed precursor solution on the substrate by heating the substrate at an annealing temperature that is from about 100° C. to about 300° C. to form a film composition comprising:
a nitrogen-containing group or ion thereof; and
a Pb-free double perovskite material represented by Formula (I):
A₂BCD₆ (I).

11. The process of claim 10, further comprising:
pre-heating the precursor solution at a pre-heating temperature that is from about 40° C. to about 150° C. prior to the dispersing the precursor solution on the substrate.

12. The process of claim 10, wherein the dispersing the precursor solution on the substrate is performed by spin coating the precursor solution on the substrate.

13. The process of claim 12, wherein the spin coating the precursor solution comprises:
rotating the substrate at 100 rpm to about 3,000 rpm; and
heating the substrate at a spin-coating temperature that is from about 90° C. to about 220° C.

14. The process of claim 10, wherein the temperature at which the precursor solution is dispersed on the substrate is operative to determine a wavelength of maximum SWIR absorbance of the film composition.

15. The process of claim 10, wherein a mol/mol % value in the precursor solution determined by Equation 1 is operative to determine a wavelength of maximum SWIR absorbance of the film composition:
$$\frac{nitrogen - containing compound}{nitrogen - containing compound + first compound} \times 100 \% \qquad ( Equation 1 )$$
wherein:
the nitrogen-containing compound in Equation 1 is a molar amount of the nitrogen-containing compound in the precursor solution; and
first compound in Equation 1 is a molar amount of the first compound in the precursor solution.

16. The process of claim 15, wherein the mol/mol % value as determined by Equation 1 is from about 5 mol/mol % to about 30 mol/mol %.

17. The process of claim 10, wherein each of the monovalent anions (D) is, independently, Cl⁻, Br⁻, I⁻, or combinations thereof.

18. The process of claim 10, wherein:
the first compound comprises cesium monovalent cation (Cs⁺), potassium monovalent cation (K⁺), sodium monovalent cation (Na⁺), or lithium monovalent cation (Li⁺);
the second compound comprises silver monovalent cation (Ag⁺), copper monovalent cation (Cu⁺), gold monovalent cation (Au⁺), or sodium monovalent cation (Na⁺);
the third compound comprises bismuth trivalent cation (Bi³⁺), antimony trivalent cation (Sb³⁺), or indium trivalent cation (In³⁺);
or combinations thereof.

19. A short-wave infrared material comprising a composition, the composition comprising:
Cs₂AgBiBr₆, Cs₂AgSbBr₆, Cs₂AgInCl₆, Cs₂CuBiBr₆, Cs₂NaBiCl₆, or combinations thereof; and
a nitrogen-containing compound or ion thereof, the nitrogen-containing compound or ion thereof comprising hydrazine, ammonia, methylamine, dimethylamine, trimethylamine, ethylamine, diethylamine, triethylamine, triisopropylamine, aziridine, diaziridine, formamidine, amidine, guanidine, hydrazinium ion, ammonium ion, methylammonium ion, dimethylammonium ion, trimethylammonium ion, ethylammonium ion, diethylammonium ion, triethylammonium ion, triisopropylammonium ion, aziridinium ion, diaziridinium ion, formamidinium ion, amidinium ion, guanidinium ion, or combinations thereof.

20. The short-wave infrared material of claim 19, wherein:
the nitrogen-containing compound or ion thereof of the composition comprises hydrazine, hydrazinium, or combinations thereof.
